(19) United States
(12) Patent Application Publication
(10) Pub. No.: US 2026/0135463 A1
(43) Pub. Date: May 14, 2026

(54) AC CURRENT DRIVEN MAGNETOHYDRODYNAMIC PUMP IN COOLANT LOOP USED TO COOL POWER CONVERTER

(71) Applicant: L3Harris Technologies, Inc., Melbourne, FL (US)

(72) Inventor: Lixin TANG, Irvine, CA (US)

(21) Appl. No.: 18/946,381

(22) Filed: Nov. 13, 2024

(51) Int. Cl. H02M 1/00; H02M 1/088; H02M 1/32; H05K 7/20

(52) U.S. Cl. CPC H02M 1/008; H02M 1/088; H02M 1/327; H05K 7/20254; H05K 7/20272; H05K 7/20927

(57) ABSTRACT

An apparatus comprises: a power converter to convert DC current to AC current and supply the AC current to a load; a cooling loop having a cold plate thermally coupled to the power converter, and a magnetohydrodynamic (MHD) pump to pump a liquid metal coolant to the cold plate to cool the power converter; and an in-line rectifier, coupled to the power converter, the MHD pump, and the load, configured to: transfer the AC current, unrectified, between the power converter and the load; and rectify the AC current into a unipolar current that flows in a single current direction over a cycle of the AC current, and supply the unipolar current to the MHD pump to compel the MHD pump to pump the liquid metal coolant to the cold plate in a single coolant flow direction over the cycle.

### TECHNICAL FIELD

The present disclosure relates to power circuit cooling systems that use magnetohydrodynamic (MHD) pumps.

### BACKGROUND

A power converter may operate in an inverter mode to convert direct current (DC) power to alternating current (AC) power, and to supply the AC power (e.g., AC load current) to an AC load. The power converter experiences power loss and dissipates heat in a direct relation to the AC load current. A liquid metal coolant (LMC) loop may be used to cool the power converter. The LMC loop, to which circuits of power converter are thermally coupled, circulates an LMC to cool the power converter. The LMC loop may include a magnetohydrodynamic (MHD) pump that pumps the LMC through the LMC loop. Conventional control of the LMC loop uses the DC power (i.e., DC current), not the AC power (i.e., the AC load current), to drive the MHD pump. The DC current is not directly related to the AC load current (i.e., the current generate by switching transistors of the power converter). Therefore, the cooling capability of the LMC loop is mismatched to the heat dissipated by the power converter. Also, the DC current has high frequency ripples, which generate extra power loss. The power converter may alternatively operate as an active rectifier, in which case the DC current switches or reverses direction relative to when the power converter operates as the inverter. This results in bi-directional LMC flow in the LMC coolant loop, which complicates the LMC loop.

### BRIEF DESCRIPTION OF THE DRAWINGS

FIG. 1 is a block diagram of an example AC power and cooling system, which includes an AC power converter system integrated with an LMC loop.

FIG. 2 is a diagram that shows further details of the AC power converter system and an AC driven magnetohydrodynamic (MHD) pump of the LMC loop, according to an embodiment.

FIG. 3 shows operation of an in-line rectifier of the AC power converter system during a positive half cycle of AC current generated by a power converter of the AC power converter system.

FIG. 4 shows operation of the in-line rectifier during a negative half cycle of the AC current.

FIG. 5 is a circuit diagram of the power converter, according to an embodiment.

FIG. 6 shows example waveforms for an AC source voltage generated by the power converter, and an AC load voltage transferred from the power converter to a load through/by the in-line rectifier.

FIG. 7 shows an example waveform for an AC load current transferred from the power converter to the load through the in-line rectifier.

FIG. 8 shows an example waveform for an MHD current generated by the in-line rectifier.

FIG. 9 is a plot of a Fast Fourier Transform (FFT) of the MHD current.

FIG. 10 is a circuit diagram of the in-line rectifier according to an embodiment.

FIG. 11 shows example waveforms for various signals that control active rectifier switches of the in-line rectifier of FIG. 10.

FIG. 12 is a block diagram of an AC power and cooling system according to another embodiment.

FIG. 13 in an illustration of power switches of the power converter thermally coupled to a cold plat of the LMC loop.

FIG. 14A is a flowchart of an example method of using an AC current driven MHD pump in a coolant loop to cool a power converter operating in an inverter mode.

FIG. 14B is a flowchart of another example method of using an AC current driven MHD pump in a coolant loop to cool a power converter operating in an active rectifier mode.

FIG. 15 is a block diagram of an example controller configured to perform operations described herein.

### DESCRIPTION OF EXAMPLE EMBODIMENTS

### Overview

In an embodiment, an apparatus comprises: a power converter to convert DC current to AC current and supply the AC current to a load; a cooling loop having a cold plate thermally coupled to the power converter, and an MHD pump to pump a liquid metal coolant to the cold plate to cool the power converter; and an in-line rectifier, coupled to the power converter, the MHD pump, and the load, configured to: transfer the AC current, unrectified, between the power converter and the load; and rectify the AC current into a unipolar current that flows in a single current direction over a cycle of the AC current, and supply the unipolar current to the MHD pump to compel the MHD pump to pump the liquid metal coolant to the cold plate in a single coolant flow direction over the cycle.

In another embodiment, an apparatus comprises: an AC grid to supply AC current; a power converter to convert the AC current to a DC current; a cooling loop having a cold plate thermally coupled to the power converter, and an MHD pump to pump a liquid metal coolant to the cold plate to cool the power converter; and an in-line rectifier, coupled to the power converter, the MHD pump, and the AC grid, configured to: transfer the AC current, unrectified, between the power converter and the AC grid; and rectify the AC current into a unipolar current that flows in a single current direction over a cycle of the AC current, and supply the unipolar current to the MHD pump to compel the MHD pump to pump the liquid metal coolant to the cold plate in a single coolant flow direction over the cycle.

### Example Embodiments

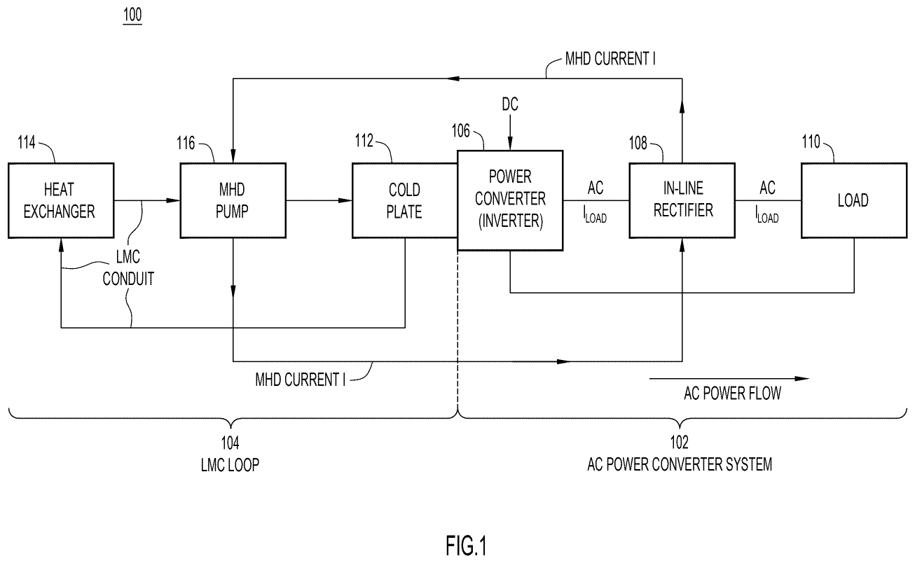

FIG. 1 is a block diagram of an AC power and cooling system 100, which includes an AC power converter system 102 integrated with a liquid metal coolant (LMC) loop 104, according to embodiments presented herein. AC power converter system 102 includes a power converter 106 that serves as a power inverter (i.e., the power converter operates in a power inverter mode), an in-line rectifier 108, and a load 110 coupled to one another. In some embodiment, AC power converter system 102 may additionally include a low-pass filter between in-line rectifier 108 and load 110, or integrated with components of the load. As used herein, the term “coupled to” (and similarly “connected to”), unless specified otherwise, covers an arrangement in which components or terminals/nodes are directly connected to each other, and an arrangement in which the components or terminals/nodes are indirectly connected to each other through one or more intermediate components.

LMC loop 104 includes a cold plate 112 to which power converter 106 is thermally coupled, a heat exchanger 114, and a magnetohydrodynamic (MHD) pump 116 all in fluid communication with each other via a contiguous LMC conduit that extends between and through the aforementioned components to form the LMC loop. MHD pump 116 circulates or pumps an electrically-conductive LMC through LMC loop 104, including cold plate 112, to cool power converter 106, as described below. In FIG. 1, the LMC conduit is represented as a series of arrows connecting the components of LMC loop 104. Directions of the arrows represent LMC-flow direction in LMC loop 104. Heat exchanger 114 may be a passive radiator or an actively cooled heat exchanger that cools the LMC when the LMC circulates through the heat exchanger.

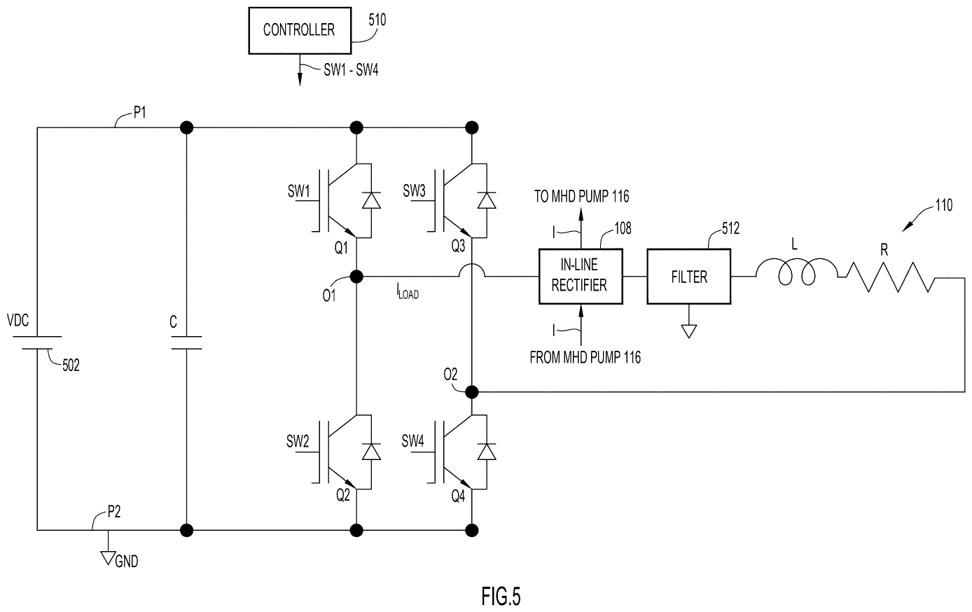

Power converter 106 includes power switches (e.g., switching transistors shown in FIG. 5) that switch on and off cyclically to convert DC power applied to an input of the power converter to AC power at an output of the power converter. The AC power includes an AC current (also referred to as a “load current I_{LOAD}”) and an AC voltage. The AC current (and the AC voltage) includes repeating cycles. Each cycle includes a positive half cycle and a negative half cycle. Power converter 106 supplies the AC power to an input of in-line rectifier 108. In-line rectifier 108 performs two functions, concurrently. First, in-line rectifier 108 passes the AC power, unrectified, from the output of power converter 106 to load 110. More generally, in-line rectifier 108 transfers the AC power, unrectified, between power converter 106 and load 110.

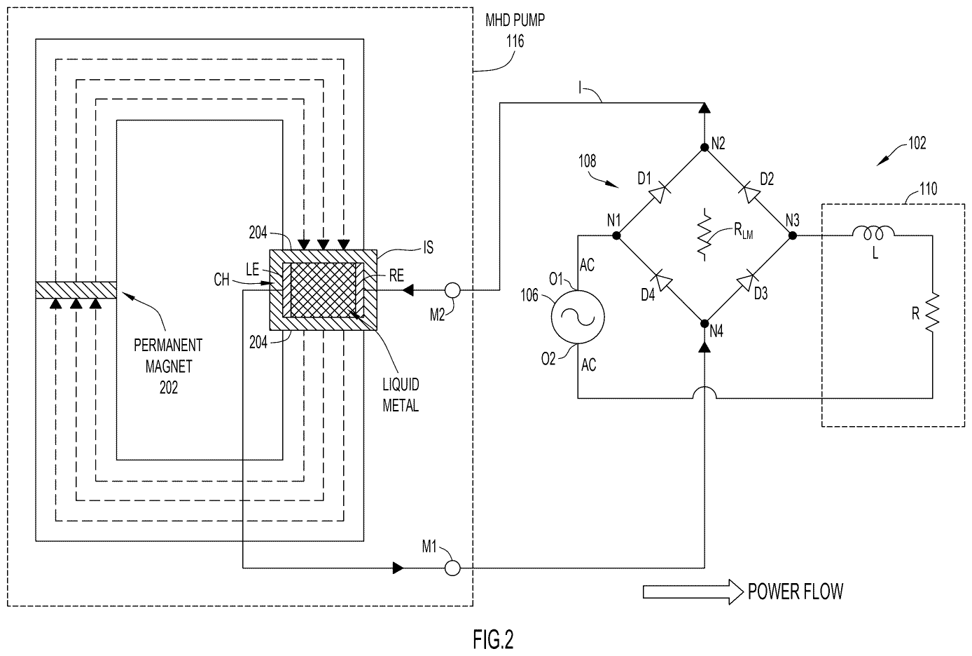

Second, in-line rectifier 108 full-wave rectifies the AC current/voltage generated by power converter 106 to produce an MHD current I, and supplies the MHD current to MHD pump 116. That is, in-line rectifier 108 serves as a current source that supplies MHD current I to MHD pump 116. MHD current I is a unipolar fully-rectified current that flows to MHD pump 116 in a single direction (i.e., always flows in the same direction) over each cycle of the AC current (i.e., across both the positive half cycle and the negative half cycle). The term “unipolar” means that MHD current I has a fixed polarity that is always negative or always positive across both half cycles of the AC current. Responsive to MHD current I and a magnetic field (shown in FIG. 2), MHD pump 116 pumps the LMC through LMC loop 104, including cold plate 112, in a single LMC-flow direction over the cycle of the AC current to cool power converter 106. In other words, MHD current I compels MHD pump 116 to pump the LMC to power converter 106. The Lorentz force that drives the LMC through LMC loop 104 is derived from, and directly related (e.g., proportional) to, the AC current. In turn, the rate of flow of the LMC is directly related (e.g., proportional) to (i.e., increases and decreases with) the AC current.

FIG. 2 is a diagram that shows further details of AC power converter system 102 and MHD pump 116, according to an embodiment. MHD pump 116 includes a permanent magnet (PM) 202 (shown in cross-section) that is C-shaped to have opposing ends 204 that are vertically spaced-apart to define a vertical gap therebetween. MHD pump 116 further includes an isolated channel CH (shown in cross-section) clamped in the gap by/between opposing ends 204. Isolated channel CH (referred to simply as “channel CH”) is in fluid communication with LMC loop 104 described above. Therefore, the LMC can flow through channel CH. Channel CH may include an outer isolation layer IS made of an isolation material and that surrounds the channel CH to isolate the LMC (in the channel CH) from other parts of the system, since the LMC has a same or similar potential as the AC voltage produced by power converter 106. Channel CH has vertically spaced-apart top and bottom sides adjacent to opposing ends 204, and horizontally spaced-apart left and right sides that collectively define a rectangular cross-section of the channel. Channel CH has a length that extends normally to the plane of the figure. The left side and the right side of channel CH include a left electrode LE and a right electrode RE connected to a node M1 and a node M2 of MHD pump 116, respectively.

PM 202 generates a magnetic field that flows across the gap/channel CH in a downward vertical direction. In-line rectifier 108 applies MHD current I to left and right electrodes LE, RE through nodes M1, M2, such that the current flows across channel CH in a horizontal direction (which is referred to as an “MHD current path”). Together, the magnetic field and MHD current I applied to the LMC contained in channel CH induce a Lorentz force on the LMC that is proportional to a magnetic field strength and a magnitude of the MHD current. The Lorentz force has a direction based on the current-flow direction (e.g., flowing horizontally right-to-left in FIG. 2) and the direction of the magnetic field (which is downward in FIG. 2), according to the Right Hand Law. The Lorentz force pumps the LMC through channel CH (i.e., along the length of the channel) in a coolant-flow direction that is normal to the plane of the figure, according to the Right Hand Law. In the example of FIG. 2, MHD current I flows right-to-left across channel CH and, according to the Right Hand Law, the Lorentz force is directed normally out of the plane of the figure. Thus, MHD pump 116 pumps the LMC in that direction.

MHD pump 116 may employ different numbers and arrangements of permanent magnets and cores to increase the magnetic field strength and, correspondingly, the Lorentz force. MHD pump 116 may also employ a field winding/coil or solenoid to generate the magnetic field.

In-line rectifier 108 includes rectifier switches coupled to nodes N1, N2, N3, and N4 of the in-line rectifier to form a ring of rectifier switches. In the embodiment of FIG. 2, the rectifier switches include diodes D1, D2, D3, and D4 coupled to nodes N1, N2, N3, and N4 to form a diode ring in a connection order N1, D1, N2, D2, N3, D3, N4, and D4. Node N1 is coupled to a first output terminal O1 of power converter 106, node N2 is coupled to right electrode RE of MHD pump 116 through node M2, node N3 is coupled to an input of load 110, and node N4 is a coupled to left electrode LE of the MHD pump through node M1. Load 110 includes an inductor L and a resistor R connected in series with each other and across (i.e., to and between) node N3 (which is connected to inductor L) and a second output terminal O2 of power converter 106.

To form the diode ring, node N1 is coupled to node N2 through diode D1, node N2 is coupled to node N3 through diode D2, node N3 is coupled to node N4 through diode D3, and node N4 is coupled to node N1 through diode D4. More specifically, (i) diode D1 has an anode (also referred to as a “positive pole”) and a cathode (also referred to as a “negative pole”) respectively coupled to nodes N1 and N2, (ii) diode D2 has an anode and a cathode respectively coupled to nodes N3 and N2, (iii) diode D3 has an anode and a cathode respectively coupled to nodes N4 and N3, and (iv) diode D4 has an anode and a cathode respectively coupled to nodes N4 and N1.

In operation, power converter 106 generates AC current at output terminals O1, O2. Diodes D1-D4 transfer the AC current to inductor L and resistor R of load 110. Concurrently, diodes D1-D4 rectify the AC current to produce unipolar, unidirectional MHD current I, and supply the same to electrodes RE, LE of MHD pump 116 via nodes N2, N4. Responsive to MHD current I, MHD pump 116 pumps the LMC through LMC loop 104 in a single direction over both the positive and negative half cycles of the AC current. As MHD current I flows across channel CH of MHD pump 116, the MHD current encounters a resistance R_{LM} presented by the LMC in the channel between electrodes RE, LE.

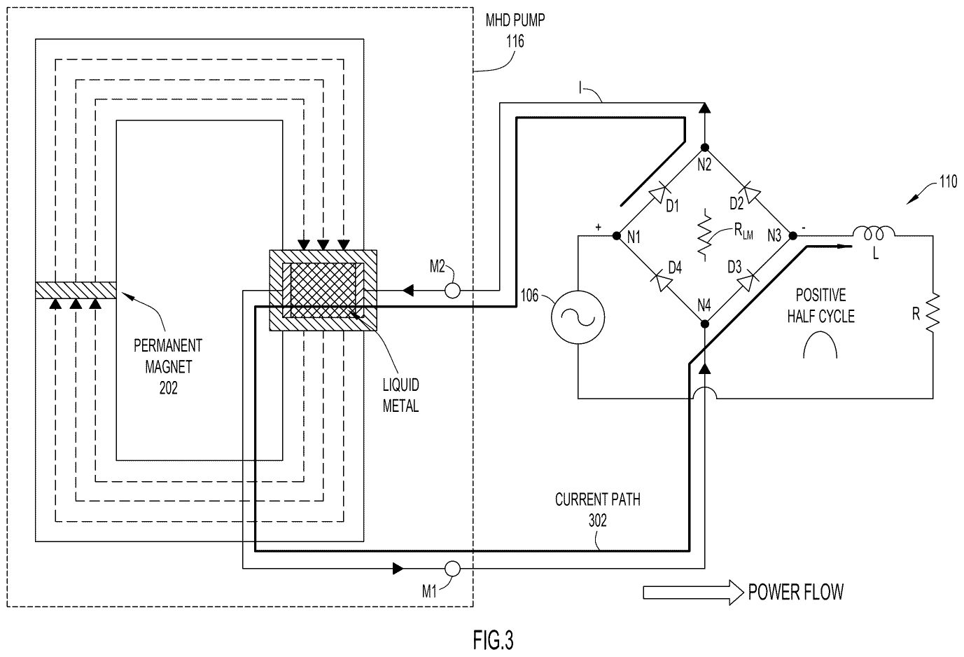

FIG. 3 shows operation of in-line rectifier 108 during the positive half cycle of the AC current. During the positive half cycle, node N1 is positive and node N3 is negative to forward bias (and turn on) only the two diodes D1 and D3 (referred to as “first rectifier switches”), and reverse bias (and turn off) only the two diodes D2 and D4 (referred to as “second rectifier switches”). That is, during the positive half cycle, diodes D1 and D3 are on, and diodes D2 and D4 are off in a complementary fashion. As a result, current flows along a first current path 302 from power converter 106 to channel CH through node N1, diode D1, and node N2, and then flows from channel CH to load 110 through node N4, diode D3, and node N3, as shown.

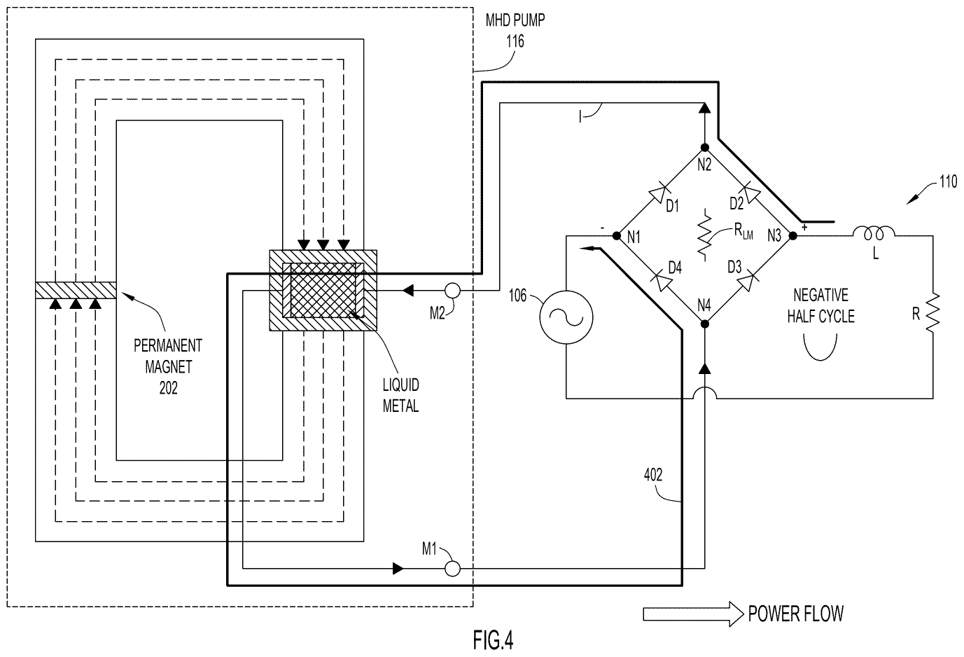

FIG. 4 shows operation of in-line rectifier 108 during the negative half cycle of the AC current. During the negative half cycle, node N1 is negative and node N3 is positive to reverse bias (and turn off) only the two diodes D1 and D3, and forward bias (and turn on) only the two diodes D2 and D4. That is, during the negative half cycle, diodes D1 and D3 are off, and diodes D2 and D4 are on in a complementary fashion. As a result, current flows along a second current path 402 from load 110 to channel CH through node N3, diode D2, and node N2, and then flows from channel CH to power converter 106 through node N4, diode D4, and node N1, as shown. Thus, over a full cycle, in-line rectifier 108 transfers the AC current bidirectionally between power converter 106 and load 110, yet supplies only unidirectional (and unipolar) MHD current I derived from the AC to current to channel CH. In summary, the first rectifier switches and the second rectifier switches are configured to be turned on and turned off in a complementary fashion responsive to the positive half cycle and the negative half cycle to transfer the AC current and rectify the AC current.

FIG. 5 is a circuit diagram of power converter 106, according to an embodiment. In the embodiment of FIG. 5, power converter 106 is a single phase power converter. In other embodiments, power converter 106 may be a multi-phase power converter. Power converter 106 includes a DC voltage source 502 and a capacitor C both connected to and across a rail P1 and rail P2, which is connected to ground (GND). DC voltage source 502 generates a DC voltage VDC and applies the same across rails P1, P2. In the example of FIG. 5, power converter 106 includes switching transistors Q1-Q4 (referred to simply as “Q1-Q4”) connected to form an H-bridge, although other configurations are possible. Q1 and Q2 having current paths connected in series with each other between rails P1, P2, and to each other at first output terminal O1 of power converter 106, to form a first leg of power converter 106. First output terminal O1 is connected to node N1 of in-line rectifier 108.

Q3 and Q4 are connected in series with each other between rails P1, P2, and to each other at second output terminal O2 of power converter 106, to form a second leg of power converter 106. Second output terminal O2 is connected to load 110 (e.g., to resistor R of the load). Q1, Q4 collectively form a first diagonal switch pair, and Q2, Q3 collectively form a second diagonal switch pair. Q1-Q4 respectively include control (e.g., gate) terminals to receive switch signals S1-S4 that individually control (i.e., turn on and turn off) Q1-Q4 depending on states of the switch signals. Example switching transistors may include, but are not limited to, an insulated-gate bipolar transistor (IGBT), a Silicon Carbide (SiC) metal oxide semiconductor field effect transistor (MOSFET), a Si MOSFET, a Gallium Nitride (GaN)-based transistor, and the like.

Power converter 106 further includes a controller 510 to generate switch signals SW1-SW4 according to a pulse width modulation (PWM) scheme, for example. Controller 510 generates switch signals SW1-SW4 as cyclical switch signals to control (i.e., turn on and turn off) Q1-Q4 in a cyclical manner. The switch signals SW1-SW4 produce the above-mentioned cycles of AC current at output terminals O1, O2. For example, during a first period, controller 510 turns on diagonal switch pair Q1, Q4 and turns off diagonal switch pair Q2, Q3, which produces a first (e.g., positive) half cycle of the AC current at output terminals O1, O2 (whereby the AC current flows into load 110). During a second period, controller 510 turns off diagonal switch pair Q1, Q4 and turns on diagonal switch pair Q2, Q3, which produces a negative cycle of AC current at output terminals O1, O2 (whereby current flows from load 110). As described above, in-line rectifier 108 rectifies the AC current to produce MHD current I such that the MHD current is unipolar (i.e., only positive or only negative) over both half cycles.

Power converter 106 may also include a filter 512 to remove undesired frequencies from the AC power generated by the power converter. Filter 512 may include one or more of a low-pass filter, a trap, and an electromagnetic interference (EMI) filter. In the example of FIG. 5, filter 512 is connected after in-line rectifier 108, e.g., between the in-line rectifier and load 110. In another example, filter 512 may be connected before in-line rectifier 108, e.g., between output terminal O1 and the in-line rectifier.

FIGS. 6-9 show multiple cycles of example voltage and current waveforms for power converter system 102.

FIG. 6 shows waveforms for an AC source voltage generated at the output of power converter 106, and an AC load voltage transferred from the power converter to load 110 through/by in-line rectifier 108. The AC load voltage is slightly lower than the AC source voltage due to small voltage drops across diodes D1-D4 and MHD channel CH. The small voltage drops can be compensated using closed-loop controllers.

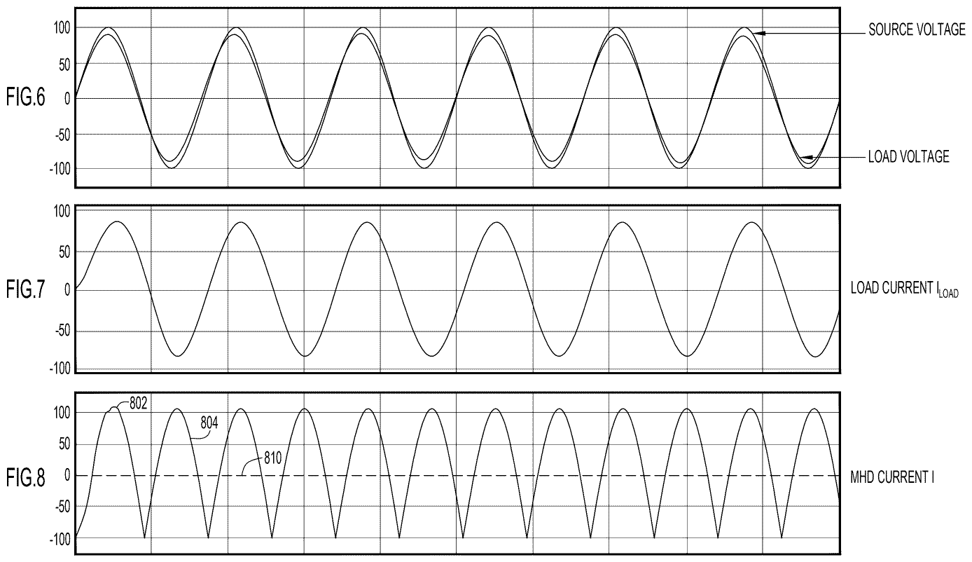

FIG. 7 shows a waveform for AC load current I_{LOAD} transferred from power converter 106 to load 110 through in-line rectifier 108.

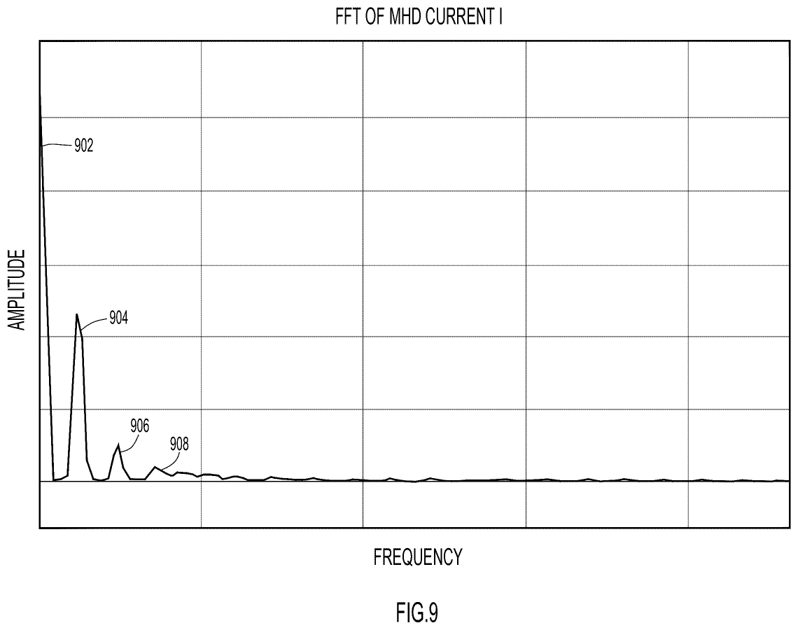

FIG. 8 shows a waveform for MHD current I generated by in-line rectifier 108. While the AC load voltage and the AC load current are sinusoidal, MHD current I is positive and unipolar. MHD current I represents a full-wave rectified current. MHD current I includes repeating unipolar cycles 802 and 804 (which appear as unipolar current humps) that coincide with corresponding positive and negative half cycles of the AC current (and the AC voltage) generated by power converter 106 and transferred to load 110. MHD current I includes a unipolar varying current component (exhibited by the repeating unipolar current humps) and an average or DC current component 810.

FIG. 9 is a plot of a Fast Fourier Transform (FFT) of MHD current I, i.e., a frequency spectrum of the MHD current. The frequency spectrum of MHD current I includes a high-level DC component 902 at zero Hz and low-level frequency harmonics 904, 906, and 908.

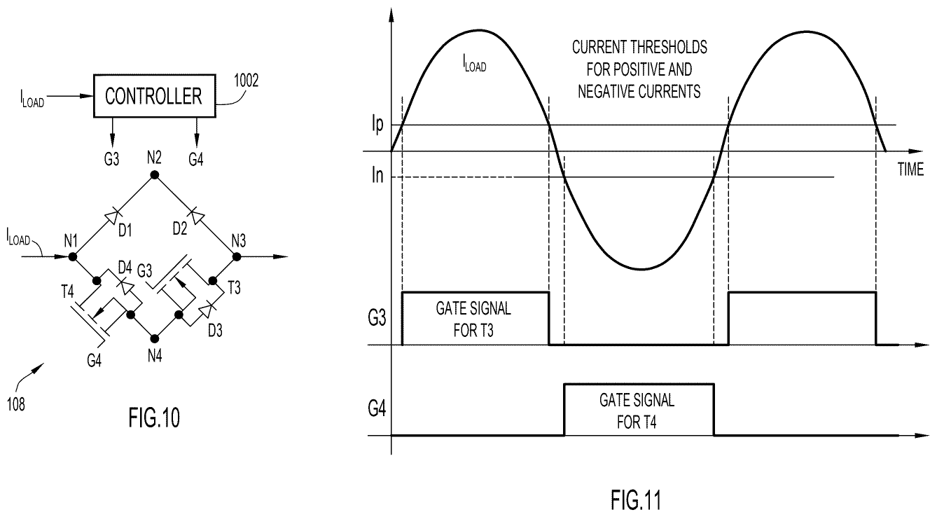

FIG. 10 is a diagram of in-line rectifier 108 according to another embodiment. The embodiment of FIG. 10 includes a FET switch T3 and a FET switch T4 (referred to simply as “T3” and “T4”) respectively added to (i.e., connected in parallel with or across) diode D3 and diode D4 (referred to simply as “D3” and “D4”), and a controller 1002 to control the FET switches responsive to the AC current (e.g., load current I_{LOAD}) generated by power converter 106. T3, T4 represent active rectifier switches. Controller 1002 may be part of controller 510. T3, T4 reduce diode loss that would otherwise occur in their absence.

T3, T4 have respective current paths connected between nodes (N3, N4), (N1, N4) and respective gates to receive respective gate signals G3, G4 generated by controller 1002. Gate signals G3, G4 individually turn on T3, T4 (such that their current paths conduct/pass current) or individually turn off the FET switches (such that their current paths block current) depending on states (e.g., logic high or logic low) of the gate signals. Controller 1002 generates gate signals G3, G4 to control T3, T4 such that they behave similarly to D3, D4 as described above in connection with FIGS. 3 and 4 during the positive and negative half cycles of I_{LOAD}.

Operation of the embodiment of in-line rectifier 108 shown in FIG. 10 is described below in connection with FIG. 11. FIG. 11 shows example waveforms for various signals that control T3, T4 of in-line rectifier 108. Moving from top-to-bottom in FIG. 11, the waveforms include (AC) load current I_{LOAD} generated by power converter 106, gate signal G3, and gate signal G4. Controller 510 sets a positive current threshold Ip for a positive half cycle of load current I_{LOAD}, and a negative current threshold In for a negative half cycle of the load current.

During the positive half cycle, D1, T3 (like D3) should be turned on (i.e., conducting), and D2, T4 (like D4) should be turned off (i.e., non-conducting). Accordingly, controller 1002 asserts gate signal G4 low to turn off T4. Concurrently, controller 1002 continuously or repeatedly compares load current I_{LOAD} against positive current threshold Ip, and asserts gate signal G3 based on results of the compare. More specifically, controller 1002 determines whether I_{LOAD} exceeds or does not exceed positive current threshold Ip. When I_{LOAD} does not exceed positive current threshold Ip, controller 1002 asserts gate signal G3 low to turn off T3. Conversely, when I_{LOAD} exceeds positive threshold Ip (which is most of the positive half cycle), controller 1002 asserts gate signal G3 high to turn on T3.

During the negative half cycle, D1, T3 (like D3) should be off, and D2, T4 (like D4) should be on. Accordingly, controller 1002 asserts gate signal G3 low to turn off T3. Concurrently, controller 1002 continuously or repeatedly compares I_{LOAD} against negative current threshold In, and asserts gate signal G4 based on results of the compare. More specifically, controller 1002 determines whether I_{LOAD} exceeds or does not exceed negative current threshold In. When I_{LOAD} does not exceed negative current threshold In in the negative sense, controller 1002 asserts gate signal G4 low to turn off T4. Conversely, when I_{LOAD} exceeds negative threshold In in the negative sense, controller 1002 asserts gate signal G4 high to turn on T4.

In the embodiment of FIG. 10, two FET switches are added to two diodes. More generally, one or more FET switches may be added to one or more of the diodes, with corresponding control of the one or more FET switches by controller 1002. In another arrangement, one or more of diodes D1-D4 may be replaced by corresponding FET switches with free-wheeling diodes.

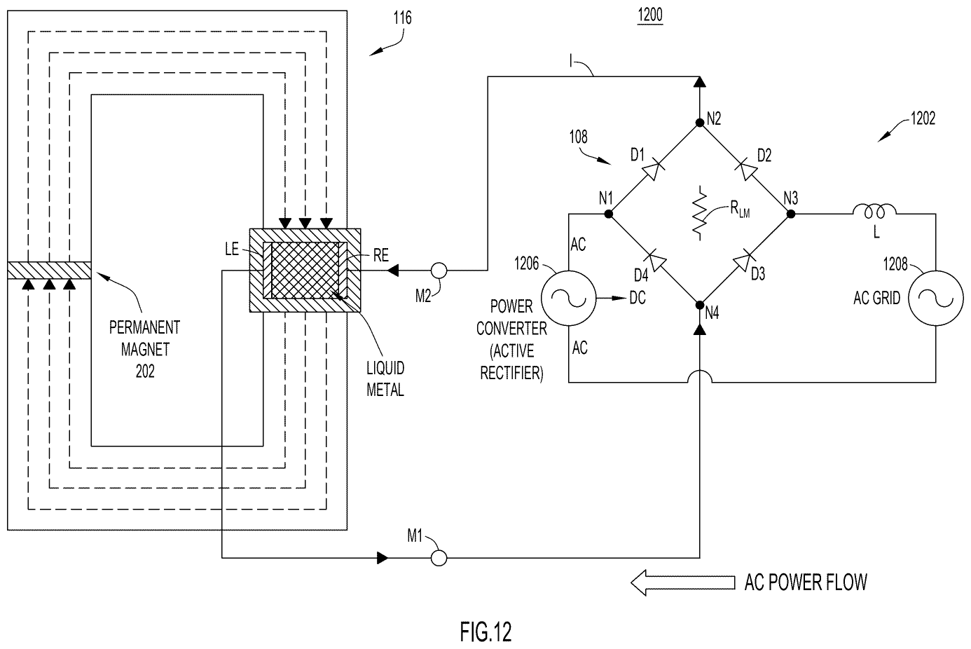

FIG. 12 is a block diagram of an AC power and cooling system 1200 according to another embodiment. AC power and cooling system 1200 includes an AC power converter system 1202 integrated with LMC loop 104. AC power converter system 1202 is similar to AC power converter system 102, except for the differences described below. Specifically, AC power converter system 1202 includes a power converter 1206 that serves as an active rectifier (instead of an inverter), and an AC grid 1208 (e.g., an AC mains circuity) that replaces resistor R of load 110. AC grid 1208 generates AC power toward power converter 1206 (the active rectifier). AC grid 1208 supplies the AC power to in-line rectifier 108. In-line rectifier 108 performs two functions concurrently. First, in-line rectifier 108 passes or transfers the AC power generated by AC grid 1208 to power converter 1206, similarly to the manner described above, except in a reverse direction. Second, in-line rectifier 108 full-wave rectifies the AC power generated by AC grid 1208 to produce the MHD current I, as described above.

Power converter 1206 receives the AC power passed by in-line rectifier 108. Power converter 1206 includes transistor switches configured similarly to those of FIG. 5, but controlled to rectify the AC power. That is, power converter 1206 controls the transistor switches to full-wave rectify the AC power, to produce DC power. LMC loop 104 cools power converter 1206 similarly to the way the LMC loop cools power converter 106, as described above. That is, responsive to (unipolar) MHD current I, MHD pump 116 circulates the LMC in a single coolant-flow direction through cold plate 112 to which power converter 1206 is thermally coupled, to cool the power converter.

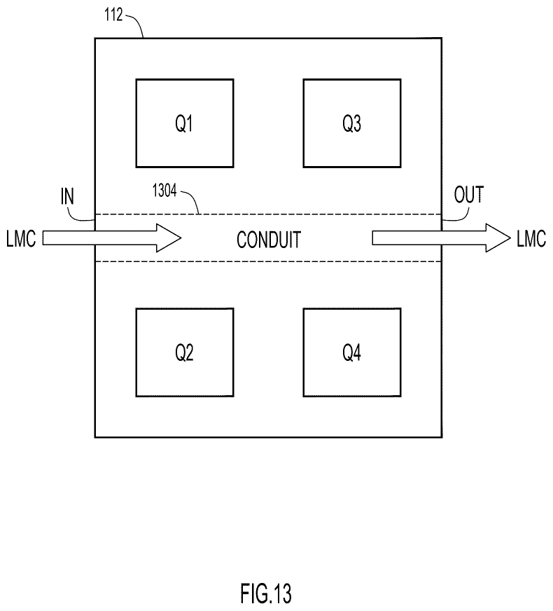

FIG. 13 shows a diagram of transistor switches Q1-Q4 thermally coupled to cold plate 112. Cold plate 112 includes a conduit 1304 that extends through the cold plate from an input port to an output port of the cold plate. The LMC circulates through conduit 1304 and cools the cold plate and transistor switches Q1-Q4.

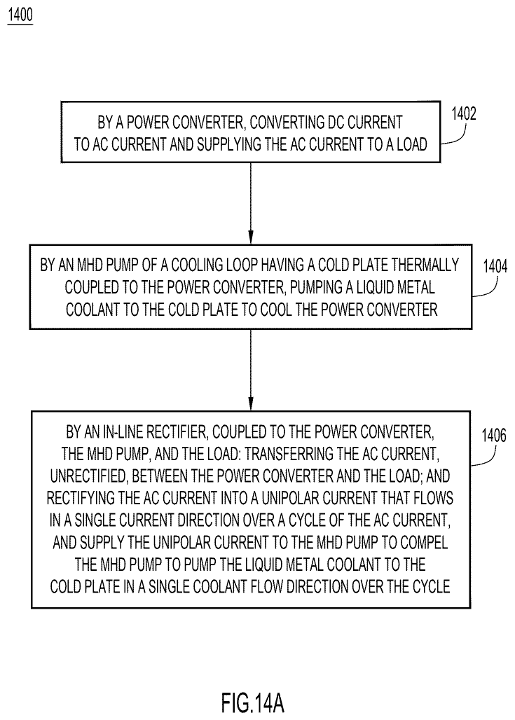

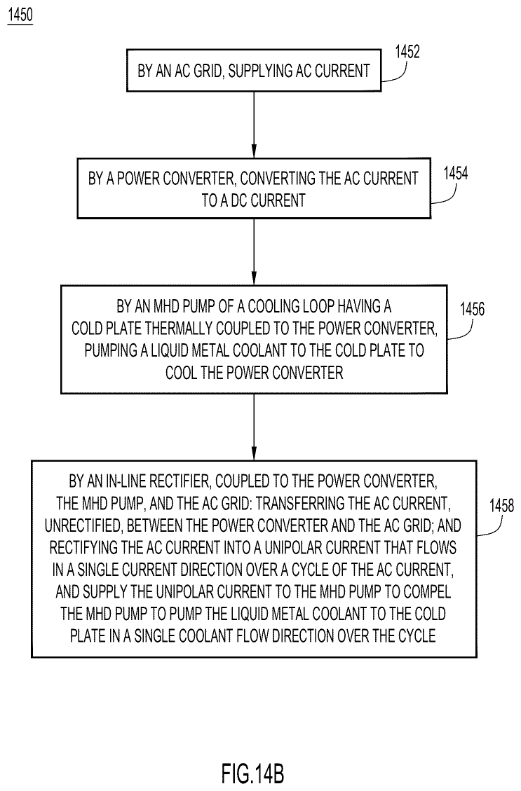

FIG. 14A is a flowchart of an example method 1400 of using an AC current driven MHD pump in a coolant loop to cool a power converter that servers as an inverter.
1402 includes, by the power converter, converting a DC current to an AC current and supplying the AC current to a load.
1404 includes, by an MHD pump of a cooling loop having a cold plate thermally coupled to the power converter, pumping an LMC to the cold plate to cool the power converter.
1406 includes, by an in-line rectifier, coupled to the power converter, the MHD pump, and the load:
a. Transferring the AC current, unrectified, between the power converter and the load.
b. Rectifying the AC current into a unipolar current that flows in a single current direction over a cycle of the AC current, and supply the unipolar current to the MHD pump to compel the MHD pump to pump the LMC to the cold plate in a single coolant flow direction over the cycle.

FIG. 14B is a flowchart of another example method 1450 of using an AC current driven MHD pump in a coolant loop to cool a power converter that serves as an active rectifier.
1452 includes, by an AC grid, supplying an AC current.
1454 includes, by a power converter (e.g., an active rectifier), converting the AC current to a DC current.
1456 includes, by an MHD pump of a cooling loop having a cold plate thermally coupled to the power converter, pumping an LMC to the cold plate to cool the power converter.
1458 includes, by an in-line rectifier, coupled to the power converter, the MHD pump, and the AC grid:
a. Transferring the AC current, unrectified, between the power converter and the AC grid.
b. Rectifying the AC current into a unipolar current that flows in a single current direction over a cycle of the AC current, and supply the unipolar current to the MHD pump to compel the MHD pump to pump the LMC to the cold plate in a single coolant flow direction over the cycle.

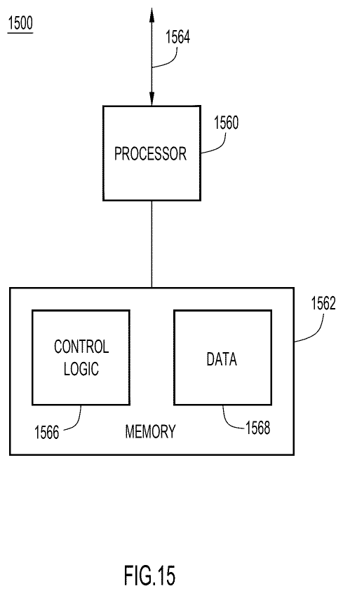

FIG. 15 is block diagram of an example controller 1500 configured to perform operations described herein. Controller 1500 may represent controllers 510 and 1002 individually when the controllers are separate controllers, or collectively when the controllers are integrated into a single controller, for example. Controller 1500 includes processor(s) 1560 and a memory 1562 coupled to one another. The aforementioned components may be implemented in hardware (e.g., a hardware processor), software (e.g., a software processor), or a combination thereof. Processor(s) 1560 communicate with other entities/processes over hardware and/or software interfaces 1564, e.g., to provide switching signals SW1-SW4 to switching transistors Q1-Q4, gate signals G3, G4 to FETs T3, T4, and to communicate with other processors, for example.

Memory 1562 stores control software 1566 (referred as “control logic”), that when executed by the processor(s) 1560, causes the processor(s), and more generally, controller 1500, to perform the various operations described herein. The processor(s) 1560 may be a microprocessor or microcontroller (or multiple instances of such components). The memory 1562 may include read only memory (ROM), random access memory (RAM), magnetic disk storage media devices, optical storage media devices, flash memory devices, electrical, optical, or other physically tangible (i.e., non-transitory) memory storage devices. Controller 1500 may also be discrete logic embedded within an integrated circuit (IC) device.

Thus, in general, the memory 1562 may comprise one or more tangible (non-transitory) computer readable storage media (e.g., memory device(s)) including a first non-transitory computer readable storage medium, a second non-transitory computer readable storage medium, and so on, encoded with software or firmware that comprises computer executable instructions. For example, control software 1566 includes logic to implement operations performed by the controller 1500. Thus, control software 1566 implements the various methods/operations described herein.

In addition, memory 1562 stores data 1568 used and produced by control software 1566.

In summary, the embodiments include in-line rectifier 108 to derive MHD current I from the AC current generated by the power switches of the power converter, and use the MHD current to pump the LMC that cools the power switches. The AC current may be taken from inductor L or resistor R or tapped from a node between the inductor and the resistor. In-line rectifier 108 converters the AC current to the MHD current I, which includes both an AC current component and a DC (average) current component; the DC component drives MHD pump 116. In-line rectifier 108 include four rectifier switches (e.g., four diodes); only two of the rectifier switches conduct during each half cycle of the AC current. In-line rectifier 108 supports bi-directional AC power flow, i.e., for an inverter mode and a rectifier mode. The Lorentz force that results from MHD current I is unipolar, whether in-line rectifier 108 operates in the inverter mode or the active rectifier mode. This results in a unidirectional coolant flow.

In some aspects, the techniques described herein relate to an apparatus including: a power converter to convert DC current to AC current and supply the AC current to a load; a cooling loop having a cold plate thermally coupled to the power converter, and a magnetohydrodynamic (MHD) pump to pump a liquid metal coolant to the cold plate to cool the power converter; and an in-line rectifier, coupled to the power converter, the MHD pump, and the load, configured to: transfer the AC current, unrectified, between the power converter and the load; and rectify the AC current into a unipolar current that flows in a single current direction over a cycle of the AC current, and supply the unipolar current to the MHD pump to compel the MHD pump to pump the liquid metal coolant to the cold plate in a single coolant flow direction over the cycle.

In some aspects, the techniques described herein relate to an apparatus, wherein: the in-line rectifier is configured to full-wave rectify the AC current into the unipolar current that flows in the single current direction during both a positive half cycle and a negative half cycle of the cycle, to cause the MHD pump to pump the liquid metal coolant to the cold plate in the single coolant flow direction during both the positive half cycle and the negative half cycle.

In some aspects, the techniques described herein relate to an apparatus, wherein: the MHD pump includes opposing electrodes on opposing sides of a channel of the MHD pump through which the liquid metal coolant flows; and the in-line rectifier includes rectifier switches coupled to the opposing electrodes and configured to supply the unipolar current to the channel via the opposing electrodes.

In some aspects, the techniques described herein relate to an apparatus, wherein: the rectifier switches include first rectifier switches and second rectifier switches configured to be turned on and turned off in a complementary fashion responsive to a positive half cycle and a negative half cycle of the cycle of the AC current to transfer the AC current and rectify the AC current.

In some aspects, the techniques described herein relate to an apparatus, wherein: the first rectifier switches and the second rectifier switches are configured to be turned on and turned off, respectively, by the positive half cycle, and turned off and turned on, respectively by the negative half cycle.

In some aspects, the techniques described herein relate to an apparatus, wherein: during the positive half cycle, the first rectifier switches form a first current path through which the unipolar current flows in the single current direction through the channel between the power converter and the load.

In some aspects, the techniques described herein relate to an apparatus, wherein: during the negative half cycle, the second rectifier switches form a second current path through which the unipolar current flows in the single current direction through the channel between the power converter and the load.

In some aspects, the techniques described herein relate to an apparatus, wherein: the rectifier switches include diodes.

In some aspects, the techniques described herein relate to an apparatus, wherein: the diodes are configured in a diode ring.

In some aspects, the techniques described herein relate to an apparatus, wherein: the rectifier switches include transistors.

In some aspects, the techniques described herein relate to an apparatus, further including: a controller to generate gate signals when a positive half cycle of the AC current exceeds a positive threshold or a negative half cycle of the AC current exceeds a negative threshold of the AC current, and to apply the gate signals to gates of corresponding ones of the transistors.

In some aspects, the techniques described herein relate to an apparatus including: an AC grid to supply AC current; a power converter to convert the AC current to a DC current; a cooling loop having a cold plate thermally coupled to the power converter, and a magnetohydrodynamic (MHD) pump to pump a liquid metal coolant to the cold plate to cool the power converter; and an in-line rectifier, coupled to the power converter, the MHD pump, and the AC grid, configured to:
transfer the AC current, unrectified, between the power converter and the AC grid; and rectify the AC current into a unipolar current that flows in a single current direction over a cycle of the AC current, and supply the unipolar current to the MHD pump to compel the MHD pump to pump the liquid metal coolant to the cold plate in a single coolant flow direction over the cycle.

In some aspects, the techniques described herein relate to an apparatus, wherein: the in-line rectifier is configured to full-wave rectify the AC current into the unipolar current that flows in the single current direction during both a positive half cycle and a negative half cycle of the cycle, to cause the MHD pump to pump the liquid metal coolant to the cold plate in the single coolant flow direction during both the positive half cycle and the negative half cycle.

In some aspects, the techniques described herein relate to an apparatus, wherein: the MHD pump includes opposing electrodes on opposing sides of a channel of the MHD pump through which the liquid metal coolant flows; and the in-line rectifier includes rectifier switches coupled to the opposing electrodes and configured to supply the unipolar current to the channel via the opposing electrodes.

In some aspects, the techniques described herein relate to an apparatus, wherein: the rectifier switches include first rectifier switches and second rectifier switches configured to be turned on and turned off in a complementary fashion responsive to a positive half cycle and a negative half cycle of the cycle of the AC current to transfer the AC current and rectify the AC current.

In some aspects, the techniques described herein relate to an apparatus, wherein: the first rectifier switches and the second rectifier switches are configured to be turned on and turned off, respectively, by the positive half cycle, and turned off and turned on, respectively by the negative half cycle.

In some aspects, the techniques described herein relate to an apparatus, wherein: during the positive half cycle, the first rectifier switches form a first current path through which the unipolar current flows in the single current direction through the channel between the power converter and the AC grid.

In some aspects, the techniques described herein relate to an apparatus, wherein: during the negative half cycle, the second rectifier switches form a second current path through which the unipolar current flows in the single current direction through the channel between the power converter and the AC grid.

In some aspects, the techniques described herein relate to an apparatus, wherein: the rectifier switches include diodes.

In some aspects, the techniques described herein relate to an apparatus, wherein: the diodes are configured in a diode ring.

The above description is intended by way of example only. Although the techniques are illustrated and described herein as embodied in one or more specific examples, it is nevertheless not intended to be limited to the details shown, since various modifications and structural changes may be made within the scope and range of equivalents of the claims.

What is claimed is:

1. An apparatus comprising:
a power converter to convert DC current to AC current and supply the AC current to a load;
a cooling loop having a cold plate thermally coupled to the power converter, and a magnetohydrodynamic (MHD) pump to pump a liquid metal coolant to the cold plate to cool the power converter; and
an in-line rectifier, coupled to the power converter, the MHD pump, and the load, configured to:
transfer the AC current, unrectified, between the power converter and the load; and
rectify the AC current into a unipolar current that flows in a single current direction over a cycle of the AC current, and supply the unipolar current to the MHD pump to compel the MHD pump to pump the liquid metal coolant to the cold plate in a single coolant flow direction over the cycle.

2. The apparatus of claim 1, wherein:
the in-line rectifier is configured to full-wave rectify the AC current into the unipolar current that flows in the single current direction during both a positive half cycle and a negative half cycle of the cycle, to cause the MHD pump to pump the liquid metal coolant to the cold plate in the single coolant flow direction during both the positive half cycle and the negative half cycle.

3. The apparatus of claim 1, wherein:
the MHD pump includes opposing electrodes on opposing sides of a channel of the MHD pump through which the liquid metal coolant flows; and
the in-line rectifier includes rectifier switches coupled to the opposing electrodes and configured to supply the unipolar current to the channel via the opposing electrodes.

4. The apparatus of claim 3, wherein:
the rectifier switches include first rectifier switches and second rectifier switches configured to be turned on and turned off in a complementary fashion responsive to a positive half cycle and a negative half cycle of the cycle of the AC current to transfer the AC current and rectify the AC current.

5. The apparatus of claim 4, wherein:
the first rectifier switches and the second rectifier switches are configured to be turned on and turned off, respectively, by the positive half cycle, and turned off and turned on, respectively by the negative half cycle.

6. The apparatus of claim 5, wherein:
during the positive half cycle, the first rectifier switches form a first current path through which the unipolar current flows in the single current direction through the channel between the power converter and the load.

7. The apparatus of claim 6, wherein:
during the negative half cycle, the second rectifier switches form a second current path through which the unipolar current flows in the single current direction through the channel between the power converter and the load.

8. The apparatus of claim 3, wherein:
the rectifier switches include diodes.

9. The apparatus of claim 8, wherein:
the diodes are configured in a diode ring.

10. The apparatus of claim 3, wherein:
the rectifier switches include transistors.

11. The apparatus of claim 10, further comprising:
a controller to generate gate signals when a positive half cycle of the AC current exceeds a positive threshold or a negative half cycle of the AC current exceeds a negative threshold of the AC current, and to apply the gate signals to gates of corresponding ones of the transistors.

12. An apparatus comprising:
an AC grid to supply AC current;
a power converter to convert the AC current to a DC current;
a cooling loop having a cold plate thermally coupled to the power converter, and a magnetohydrodynamic (MHD) pump to pump a liquid metal coolant to the cold plate to cool the power converter; and
an in-line rectifier, coupled to the power converter, the MHD pump, and the AC grid, configured to:
transfer the AC current, unrectified, between the power converter and the AC grid; and
rectify the AC current into a unipolar current that flows in a single current direction over a cycle of the AC current, and supply the unipolar current to the MHD pump to compel the MHD pump to pump the liquid metal coolant to the cold plate in a single coolant flow direction over the cycle.

13. The apparatus of claim 12, wherein:
the in-line rectifier is configured to full-wave rectify the AC current into the unipolar current that flows in the single current direction during both a positive half cycle and a negative half cycle of the cycle, to cause the MHD pump to pump the liquid metal coolant to the cold plate in the single coolant flow direction during both the positive half cycle and the negative half cycle.

14. The apparatus of claim 12, wherein:
the MHD pump includes opposing electrodes on opposing sides of a channel of the MHD pump through which the liquid metal coolant flows; and
the in-line rectifier includes rectifier switches coupled to the opposing electrodes and configured to supply the unipolar current to the channel via the opposing electrodes.

15. The apparatus of claim 14, wherein:
the rectifier switches include first rectifier switches and second rectifier switches configured to be turned on and turned off in a complementary fashion responsive to a positive half cycle and a negative half cycle of the cycle of the AC current to transfer the AC current and rectify the AC current.

16. The apparatus of claim 15, wherein:
the first rectifier switches and the second rectifier switches are configured to be turned on and turned off, respectively, by the positive half cycle, and turned off and turned on, respectively by the negative half cycle.

17. The apparatus of claim 16, wherein:
during the positive half cycle, the first rectifier switches form a first current path through which the unipolar current flows in the single current direction through the channel between the power converter and the AC grid.

18. The apparatus of claim 17, wherein:
during the negative half cycle, the second rectifier switches form a second current path through which the unipolar current flows in the single current direction through the channel between the power converter and the AC grid.

19. The apparatus of claim 14, wherein:
the rectifier switches include diodes.

20. The apparatus of claim 19, wherein:
the diodes are configured in a diode ring.
